(19) United States
(12) Patent Application Publication
(10) Pub. No.: US 2008/0149997 A1
(43) Pub. Date: Jun. 26, 2008

(54) Nonvolatile memory device and method of operating the same

(75) Inventors: Young-gu Jin, Hwaseong-si (KR); Ki-ha Hong, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/892,850

(22) Filed: Aug. 28, 2007

(30) Foreign Application Priority Data
Dec. 20, 2006 (KR) 10-2006-0131152

(51) Int. Cl. H01L 29/76; G11C 11/34

(52) U.S. Cl. 257/319; 365/185.27; 365/185.29; 257/E29.226

(57) ABSTRACT

Provided are a nonvolatile memory device and a method of operating the same, which have increased operation reliability and which facilitate increased integration. The nonvolatile memory device may include a semiconductor substrate, and at least one charge storage layer may be provided on a semiconductor substrate. At least one control gate electrode may be provided on the at least one charge storage layer. At least one first auxiliary gate electrode may be disposed on one side of and apart from the at least one charge storage layer and isolated from the semiconductor substrate.

### PRIORITY STATEMENT

This application claims priority under 35 U.S.C. § 119 to Korean Patent Application No. 10-2006-0131152, filed on Dec. 20, 2006, in the Korean Intellectual Property Office (KIPO), the entire contents of which are incorporated herein by reference.

### BACKGROUND

1. Field

Example embodiments relate to a memory device and a method of operating the same. Other example embodiments relate to a nonvolatile memory device which is capable of storing data using a charge storage layer, and a method of operating the same.

2. Description of the Related Art

In recent years, nonvolatile memory devices used in semiconductor products have been more highly integrated due to the trend toward miniaturization of semiconductor products. Accordingly, a nonvolatile memory device having a three-dimensional structure which is capable of enhancing a degree of integration compared to a conventional one-dimensional structure has been studied. However, in order to implement the nonvolatile memory device having the three-dimensional structure, a semiconductor substrate, which is capable of being stacked instead of a conventional bulk silicon wafer, may be needed. However, recent stackable semiconductor substrates, e.g., a nanowire and/or a compound semiconductor, may have difficulty forming source and drain regions through impurity doping.

Furthermore, as the degree of integration in the nonvolatile memory device is increased, the width and spacing of a control gate electrode may be reduced. Accordingly, the width and spacing of charge storage layers have also been reduced, so that an interference phenomenon between charge storage layers may occur. For example, in a write operation of the nonvolatile memory device, charges stored in adjacent charge storage layers may affect each other, which changes a threshold voltage of unit cells. As a result, distinguishing between a program state and an erase state due to this read interference may become difficult, and thus, the operation reliability of the nonvolatile memory device may be decreased.

### SUMMARY

Example embodiments provide a nonvolatile memory device with increased operation reliability and integration. Example embodiments also provide a method of operating the nonvolatile memory device.

According to example embodiments, there is provided a nonvolatile memory device. The nonvolatile memory device may include a semiconductor substrate. At least one charge storage layer may be provided on the substrate. At least one control gate electrode may be provided on the at least one charge storage layer. At least one first auxiliary gate electrode may be disposed on one side of and apart from the at least one charge storage layer, and may be isolated from the semiconductor substrate.

The nonvolatile memory device may further include at least one second auxiliary gate electrode which may be disposed on the other side of and apart from the at least one charge storage layer and may be isolated from the semiconductor substrate. The at least one control gate electrode may be a plurality of control gate electrodes which are disposed across the semiconductor substrate, the at least one charge storage layer may be a plurality of charge storage layers which are interposed between the semiconductor substrate and the plurality of control gate electrodes, and the at least one first auxiliary gate electrode may be a plurality of first auxiliary gate electrodes which are alternately disposed between the plurality of charge storage layers and which are isolated from the semiconductor substrate.

The at least one second auxiliary gate electrode may be a plurality of second auxiliary gate electrodes which are alternately disposed with the plurality of first auxiliary gate electrodes between the plurality of charge storage layers and which are isolated from the semiconductor substrate. The nonvolatile memory device may further include a channel region defined in the semiconductor substrate under the at least one charge storage layer and the at least one first auxiliary gate electrode and the at least one second auxiliary gate electrode. The semiconductor substrate may include a bulk semiconductor wafer, a semiconductor nanowire on a body insulation layer or a semiconductor layer on the body insulation layer.

According to example embodiments, there is provided a method of operating the nonvolatile memory device. The method of operating a nonvolatile memory device may include applying a first program voltage to a control gate electrode and a second program voltage to a first auxiliary gate electrode in order to inject a charge from a semiconductor substrate to a charge storage layer. A channel region of the semiconductor substrate under the control gate electrode and the first auxiliary gate electrode may be turned on.

The nonvolatile memory device may further include a second auxiliary gate electrode isolated from the semiconductor substrate and on the other side of the charge storage layer, and the second program voltage may be applied to the second auxiliary gate electrode. The method may further include applying a first read voltage to the control gate electrode and a second read voltage to the first auxiliary gate electrode, which reads data from the charge storage layer. A channel region of the semiconductor substrate under the first auxiliary gate electrode may be turned on, and the channel region of the semiconductor substrate under the charge storage layer may be turned on or turned off depending on a data state in the charge storage layer.

The nonvolatile memory device may further include a second auxiliary gate electrode isolated from the semiconductor substrate and on the other side of the charge storage layer, and the second read voltage may be applied to the second auxiliary gate electrode. The method may further include applying an erase voltage to the first auxiliary gate electrode, which erases data stored in the charge storage layer. The control gate electrode and the semiconductor substrate may be grounded.

### BRIEF DESCRIPTION OF THE DRAWINGS

Example embodiments will be more clearly understood from the following detailed description taken in conjunction with the accompanying drawings. FIGS. 1-18 represent non-limiting, example embodiments as described herein.

FIG. 1 is a schematic arrangement plan of a nonvolatile memory device according to example embodiments;

FIG. 2 is a cross-sectional view taken along a line II-II′ in the nonvolatile memory device of FIG. 1;

FIG. 3 is a cross-sectional view taken along a line III-III′ in the nonvolatile memory device of FIG. 1;

FIGS. 4-7 are cross-sectional views of a nonvolatile memory device according to example embodiments;

FIG. 8 is a schematic arrangement plan of a nonvolatile memory device according to example embodiments;

FIG. 9 is a schematic arrangement plan for illustrating a program operation of a nonvolatile memory device according to example embodiments;

FIG. 10 is a cross-sectional view for illustrating a program operation of a nonvolatile memory device according to example embodiments;

FIG. 11 is a graph of electrical field distribution obtained by simulation, for showing a program operation of a nonvolatile memory device according to example embodiments;

FIG. 12 is a schematic arrangement plan for illustrating a read operation of a nonvolatile memory device according to example embodiments;

FIG. 13 and FIG. 14 are cross-sectional views for illustrating a read operation of a nonvolatile memory device according to example embodiments;

FIG. 15 is a graph of a voltage-current characteristic obtained by simulation for illustrating a read operation of a nonvolatile memory device according to example embodiments;

FIG. 16 is a schematic arrangement plan for illustrating an erase operation of a nonvolatile memory device according to example embodiments;

FIG. 17 is a cross-sectional view for illustrating an erase operation of a nonvolatile memory device according to example embodiments; and

FIG. 18 is a graph of electrical field distribution obtained by simulation for illustrating an erase operation of a nonvolatile memory device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully hereinafter with reference to the accompanying drawings, in which example embodiments. Example embodiments may, however, be embodied in many different forms and should not be construed as being limited to the embodiments set forth herein. Rather, these embodiments are provided so that this disclosure will be thorough and complete, and will fully convey the scope of example embodiments to those skilled in the art. In the drawings, the thicknesses of layers and regions are exaggerated for clarity. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

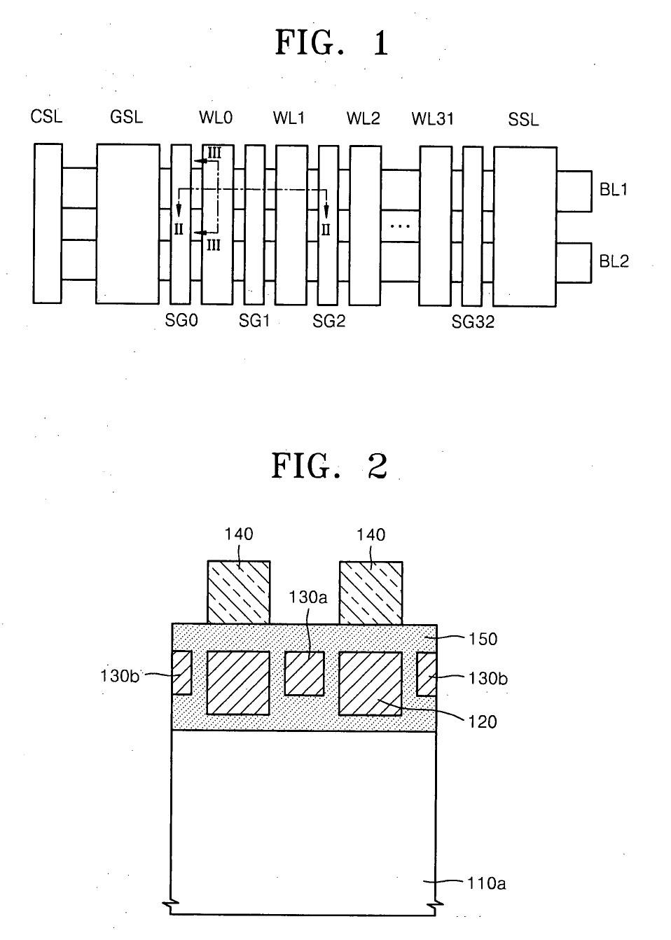

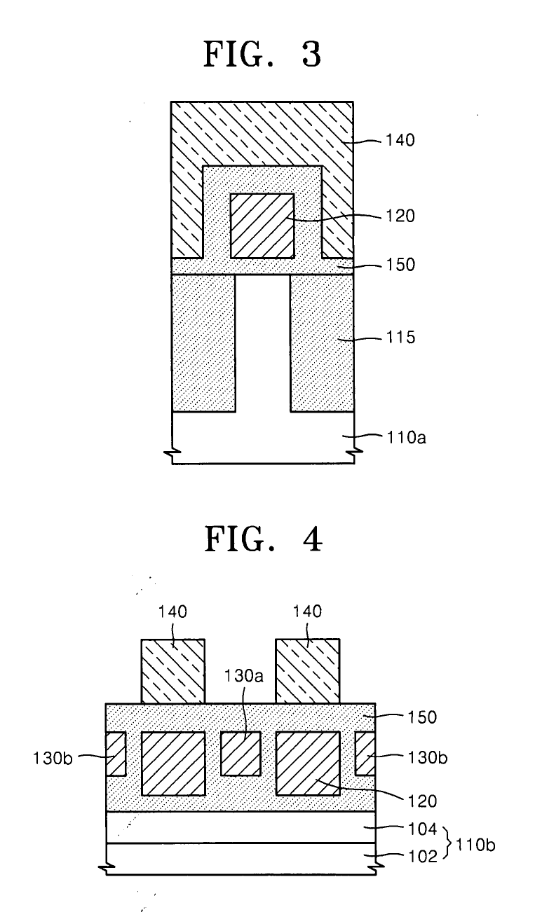

FIG. 1 is a schematic arrangement plan of a nonvolatile memory device according to example embodiments; FIG. 2 is a cross-sectional view taken along a line II-II′ in the nonvolatile memory device of FIG. 1; and FIG. 3 is a cross-sectional view taken along a line III-III′ in the nonvolatile memory device of FIG. 1. FIG. 1 shows illustratively a memory device having a NAND structure, and FIG. 2 shows a cross-section in a bit line direction, and FIG. 3 shows a cross-section in a word line direction.

Referring to FIG. 1, a plurality of bit lines BL1 and BL2 may be arranged in rows. A plurality of word lines WL0, WL1, WL2 . . . , and WL31 may be arranged in columns across the bit lines BL1 and BL2. A string selection line SSL and a source selection line GSL may be disposed outside the plurality of word lines WL0, WL1, WL2 . . . , and WL31. Bit lines BL1 and BL2 may be connected to a common source line CSL outside the source selection line GSL. A plurality of auxiliary lines SG0, SG1, SG2 . . . , and SG32 may be disposed between the source selection line GSL, word lines WL0, WL1, WL2 . . . , and WL31 and a string selection line SSL, respectively.

The plurality of word lines WL0, WL1, WL2 . . . , and WL31 may control the memory transistor, and the string selection line SSL and the source selection line GSL may control the MOS transistor. The auxiliary lines SG0, SG1, SG2 . . . , and SG32 instead of a source and a drain may receive and send charges from and to the memory transistors and cause channels of the memory transistors to be connected to each other.

The number of bit lines BL1 and BL2 and word lines WL0, WL1, WL2 . . . , and WL31 may be suitably selected according to memory capacity, and it does not limit the scope of example embodiments. Referring to FIG. 1-FIG. 3, the semiconductor substrate 110a may include any one of the bit lines BL1 and BL2. Control gate electrodes 140 may correspond to the word lines WL0 and WL1 or may constitute a portion of the word lines WL0 and WL1. The first and second auxiliary gate electrodes 130a and 130b may correspond to the auxiliary lines SG0, SG1 and SG2 or may constitute a portion of the auxiliary lines SG0, SG1 and SG2.

FIG. 2 and FIG. 3 show cross-sections in bit line and word line directions of the memory transistors of FIG. 1, respectively. However, because a structure which includes the source selection line GSL and the string selection line SSL is well known by those skilled in the art, its detailed description is omitted.

For example, the semiconductor substrate 110a may be a bulk semiconductor wafer, e.g., a silicon wafer. The source and drain regions formed by impurity doping may not be defined separately in the memory transistor region of the semiconductor substrate 110a. However, the source and drain regions may be formed in a portion of the MOS transistor including the string selection line SSL and the source selection line GSL. Viewing in the word line direction, a device isolation film 115 (see FIG. 3) may be interposed between bit lines BL1 and BL2. Accordingly, the bit lines BL1 and BL2 may be defined as active regions which are defined by a device isolation film 115 in the semiconductor substrate 110a.

Charge storage layers 120 may be provided on the semiconductor substrate 110a. The control gate electrodes 140 may be provided on the charge storage layers 120, and may be extended in the word line direction. For example, the control gate electrodes 140 may be extended so as to enclose a sidewall of charge storage layers 120 along the word line direction. Accordingly, an area facing the control gate electrodes 140 and the charge storage layers 120 may become large, so that a voltage coupling ratio between them may be increased.

The charge storage layers 120 may include a material which is capable of storing charge, e.g., polysilicon, metal, a silicon nitride film, quantum dots and/or nanocrystals. The quantum dots and nanocrystals may include micro structures of metal or semiconductor material, and may be used to trap charge. The control gate electrodes 140 may include a conductor, e.g., metal, polysilicon and/or metal silicide.

When viewing one memory transistor or one cell as a reference, a first auxiliary gate electrode 130a may be arranged on one side of the charge storage layers 120, and a second auxiliary gate electrode 130b may be arranged on another side of the charge storage layers 120. When viewing an array of memory cells, the first and second auxiliary gate electrodes 130a and 130b may be arranged alternately between charge storage layers 120. Therefore, the first and second auxiliary gate electrodes 130a and 130b may be shared in adjacent memory transistors. The first and second auxiliary gate electrodes 130a and 130b may include a conductive layer, e.g., metal and/or polysilicon. The first and second auxiliary gate electrodes 130a and 130b are only distinguished for the sake of convenience, however they may be referred reversely each other or may be referred to with the same reference numeral.

Optionally, an interlayer insulation film 150 may be interposed between the control gate electrode 140, the charge storage layer 120, and the first and second auxiliary gate electrodes 130a and 130b. Herein, the interlayer insulation film 150 may be used in the generic sense, and accordingly it may also include insulation films which are composed of different materials. For example, the interlayer insulation film 150 between the charge storage layer 120 and the semiconductor substrate 110a may be referred to as a tunneling insulation film (not shown), and the interlayer insulation film 150 between the control gate electrode 140 and the charge storage layer 120 may be referred to as a blocking insulation film. The tunneling insulation film and blocking insulation film may be formed of the same material, and also may be formed of different materials. For example, the interlayer insulation film 150 may include any one of an oxide film, a nitride film, and a high-k film, a stack of these films and/or a combination of these films.

The channel region 112 (see FIG. 10) may be defined in the semiconductor substrate 110a under the charge storage layers 120 and the first and second auxiliary gate electrodes 130a and 130b. The channel region 112 may form a channel which becomes a conducting path of charge when the memory transistors or the MOS transistor is turned on. However, in example embodiments, the channel region 112 may be extended to under the first and second auxiliary gate electrodes 130a and 130b, which is different from a conventional nonvolatile memory device. In other words, instead of conventional source and drain regions, the channel region 112 may be extended. The ability to turn on this channel region 112 may be controlled by the control gate electrode 140 and the first and second auxiliary gate electrodes 130a and 130b, as will be described later in a method of operation.

According to the nonvolatile memory device of example embodiments, the source and drain regions inside the memory transistors are omitted, and instead the first and second auxiliary gate electrodes 130a and 130b may be used. The first and second auxiliary gate electrodes 130a and 130b may be formed with a thinner line width than that of the source and drain regions formed by impurity doping, thereby improving the degree of integration in the nonvolatile memory device.

In addition, because the first and second auxiliary gate electrodes 130a and 130b shield the charge storage layers 120, the effect of the charge in the charge storage layers 120 on adjacent memory transistors may be minimized or reduced. Accordingly, interference between the charge storage layers 120, for example, interference upon a read operation, may be suppressed. As a result, the charge storage layers 120 may be disposed more closely than in the related art, and the degree of integration of a nonvolatile memory device may be increased.

Although the nonvolatile memory device is arranged in a NAND structure, example embodiments may not be limited to this structure. Accordingly, it is obvious that the nonvolatile memory device according to example embodiments may also be applied to other structures which use a structure of one memory transistor as a unit cell in FIG. 2 and FIG. 3.

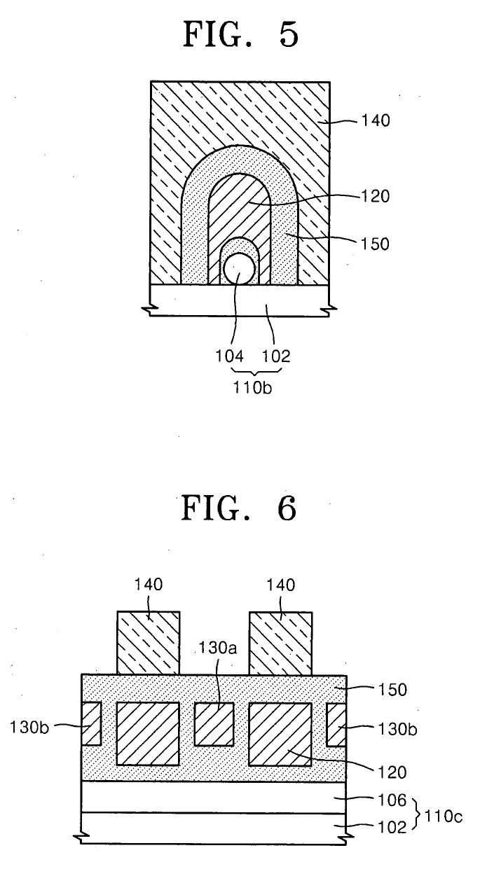

FIG. 4 and FIG. 5 are cross-sectional views showing a nonvolatile memory device according to example embodiments. The nonvolatile memory device illustrated in FIGS. 4 and 5 is a modification of the nonvolatile memory device of FIG. 2 and FIG. 3. Accordingly, the nonvolatile memory device illustrated in FIGS. 4 and 5 may be incorporated in the nonvolatile memory device in FIG. 1. Hereinafter, overlapping descriptions between both embodiments will be omitted and only differences between them will be described.

Referring to FIG. 4 and FIG. 5, the semiconductor substrate 110b may include a plurality of nanowires 104 on the body insulation layer 102. For example, the nanowires 104 may have a cylindrical structure and may be extended in the bit line direction. The shape of the nanowires 104 may be only an illustrative example, and the nanowires may be a cylindrical shape or another shape. The nanowires 104 generally refer to something formed of a nano size material, however recently, ‘nano size’ is broadly interpreted as something having a more fine size. For example, the nanowires 104 may include a semiconductor material, e.g., silicon (Si), silicon-germanium (SiGe), GaAs and/or ZnO. The charge storage layers 120 may be arranged so as to enclose a side surface of the nanowires 104 along the word line direction. However, the scope of example embodiments may not be limited to such a shape of charge storage layers 120.

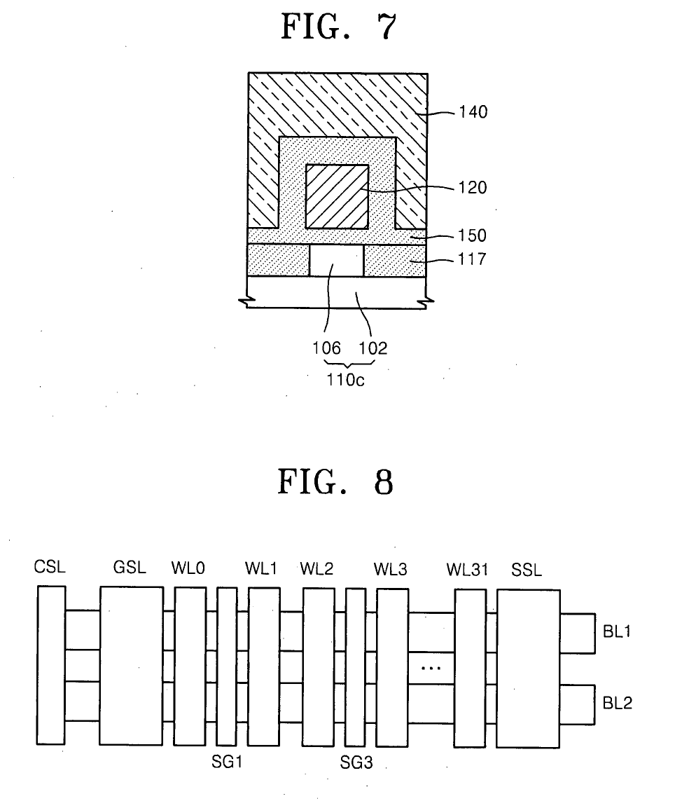

FIG. 6 and FIG. 7 are cross-sectional views of a nonvolatile memory device according to example embodiments. The nonvolatile memory device illustrated in FIGS. 6 and 7 is a modification of the nonvolatile memory device of FIG. 2 and FIG. 3. Therefore, the nonvolatile memory device illustrated in FIGS. 6 and 7 may be incorporated in the nonvolatile memory device of FIG. 1. Hereinafter, overlapping descriptions in both embodiments will be omitted and only differences between them will be described.

Referring to FIG. 6 and FIG. 7, the semiconductor substrate 110c may include semiconductor layers 106 on the body insulation layer 102. A device isolation film 117 may be interposed between the semiconductor layers 106. For example, the semiconductor layers 106 may include a thin film layer of semiconductor material, e.g., silicon (Si), silicon-germanium (SiGe) and/or a thin film layer of GaAs. For example, the semiconductor substrate 110c may be a silicon-on-insulator (SOI) substrate.

FIG. 8 is a schematic arrangement plan of a nonvolatile memory device according to example embodiments. The nonvolatile memory device illustrated in FIG. 8 is a modification of the nonvolatile memory device in FIG. 1. Therefore, the nonvolatile memory device illustrated in FIG. 8 further refers to not only the arrangement in FIG. 1, but also the cross-sectional structure in FIG. 3. Therefore, overlapping descriptions between example embodiments illustrated in FIG. 1 and FIG. 8 will be omitted.

Referring to FIG. 8, auxiliary lines SG1, SG3 may be alternately arranged between each of the word lines WL0, WL1, WL2, WL3 . . . , and WL31. Compared with FIG. 1, the first auxiliary lines SG1, SG3 may be alternately arranged between each of the word lines WL0, WL1, WL2, WL3 . . . , and WL31, and the second auxiliary lines SG2 . . . , and SG32 may be omitted.

When the second auxiliary lines SG2 . . . , and SG32 are omitted, the source region and drain regions (not shown) may be defined in the bit lines BL1 and BL2 under the second auxiliary lines SG2 . . . , and SG32. Therefore, the first auxiliary lines SG1 and SG3, and the source and drain regions may be alternately arranged between the word lines WL0, WL1, WL2, WL3 . . . , and WL31.

Compared with the cross-section of FIG. 2 and FIG. 3, the first auxiliary gate electrodes 130a may be alternately arranged between the charge storage layers 120 and the second auxiliary gate electrode 130b may be omitted. The source region and drain region may be defined in the semiconductor substrate 110a under the omitted second auxiliary gate electrode 130b. Therefore, the first auxiliary gate electrode 130a and the source and drain regions may be alternately arranged in different levels between the charge storage layers 120. In example embodiments, the second auxiliary lines SG2 . . . , and SG32 may remain, and the first auxiliary lines SG1 and SG3 may be omitted. In addition, the structure of example embodiments may also be applied to the structures in FIGS. 3-6.

A method of operating the nonvolatile memory device according to example embodiments will be described below with reference to FIG. 8-FIG. 18. FIG. 8-FIG. 18 will be described with reference to the nonvolatile memory device of FIGS. 1-3.

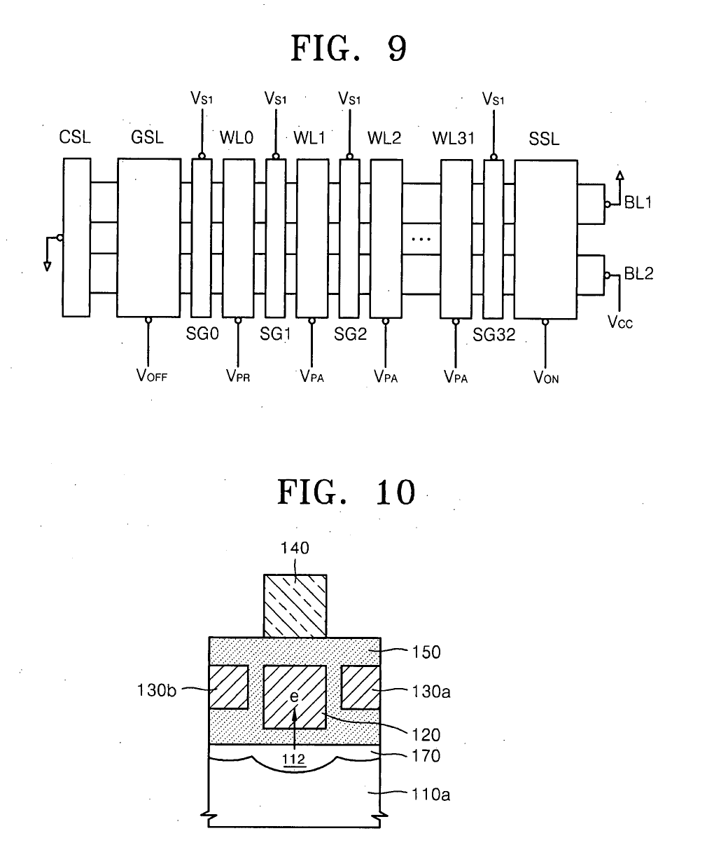

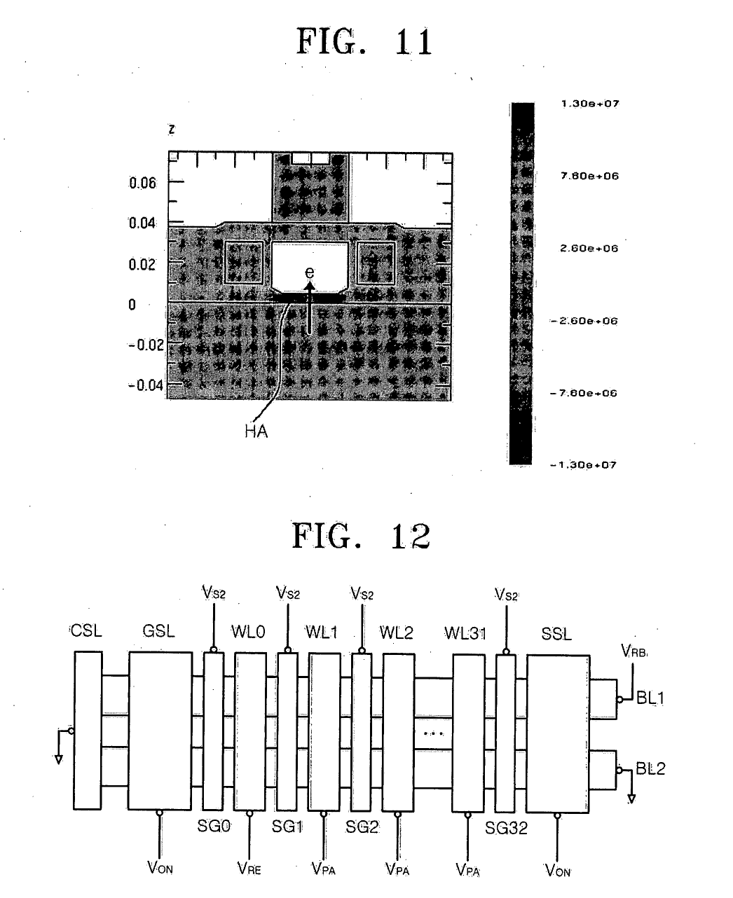

FIG. 9 is a schematic arrangement plan for illustrating a program operation of a nonvolatile memory device according to example embodiments, and FIG. 10 is a cross-sectional view for illustrating a program operation of a nonvolatile memory device according to example embodiments, and FIG. 11 is a graph of electrical field distribution obtained by simulation for illustrating a program operation of a nonvolatile memory device according to example embodiments.

Referring to FIG. 9, a cell, which includes one memory transistor, e.g., a first word line WL0 and a first bit line BL1, may be selected. A first program voltage V_{PR} may be applied to the selected first word line WL0, and a pass voltage V_{PA} may be applied to other word lines WL1, WL2 . . . , and WL31. The second program voltage V_{S1} may be applied to the auxiliary lines SG0, SG1, SG2 . . . , and SG32. The common source line CSL and the first bit line BL1 may be grounded, and a boosting voltage V_{CC} may be applied to the second bit line BL2. A turn-off voltage V_{OFF} may be applied to the source selection line GSL, and a turn-on voltage V_{ON} may be applied to the string selection line SSL.

For example, a first program voltage V_{PR} may be a voltage above about 15 V, and a second program voltage V_{S1} may be a voltage above about 5V. The channel boosting voltage V_{CC} and the turn-on voltage V_{ON} may be a voltage of about 2-4 V, and the pass voltage V_{PA} may be a voltage above about 7 V. The turn-off voltage V_{OFF} may be a voltage of about 0V. However, these voltage ranges are only for illustrative purpose, and may be varied depending on the dimensions of the nonvolatile memory device.

Referring to FIG. 10, a first program voltage V_{PR} may be applied to the control gate electrode 140 and a second program voltage V_{S1} may be applied to the first and second auxiliary gate electrodes 130a and 130b. The channel region 112 may be turned on so that the channel 170 may be formed. In addition, charge, e.g., electrons e, may be injected from the channel region 112 to the charge storage layer 120 by an electrical field between the charge storage layer 120 and the semiconductor substrate 110a. Accordingly, a memory transistor, which includes the charge storage layer 120 into which the electrons e are injected, may be maintained in a program state.

Referring to FIG. 10 and FIG. 11 together, an electrical field HA above about 13 MV/cm may be made between the charge storage layer 120 and the semiconductor substrate 110a. In FIG. 11, the colored portion indicates the intensity of the electrical field. The increased electrical field intensity may be sufficient to cause the tunneling of electrons e.

The method of programming one cell as described above may also be applied similarly to other cells. In addition, similar to the example embodiment of FIG. 8, in which the second auxiliary line is omitted, and in this case, the source and drain regions and the channel region may exist together.

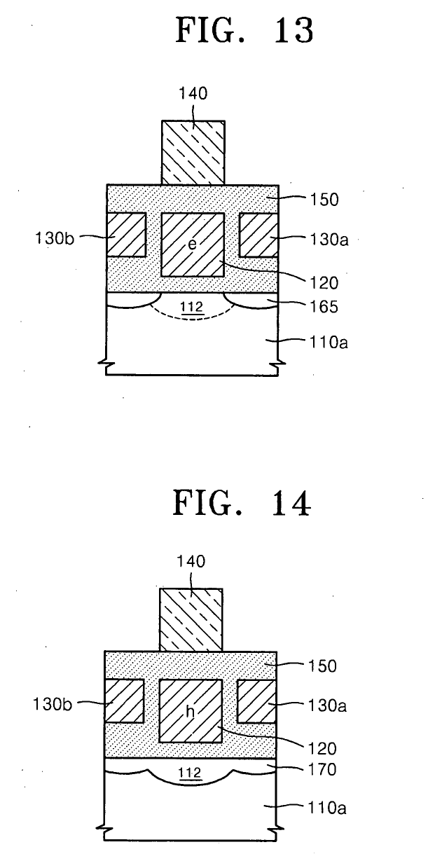

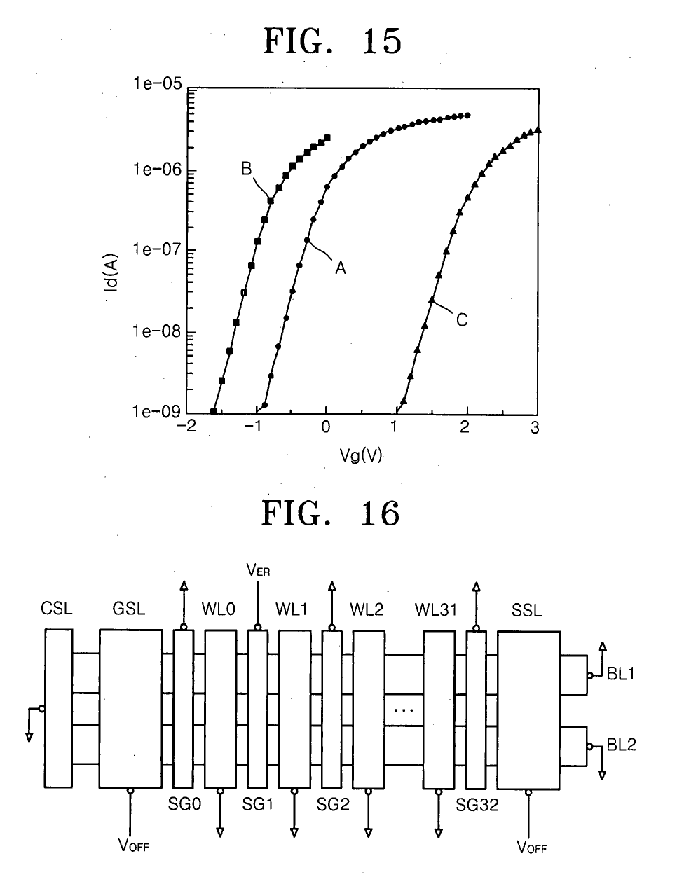

FIG. 12 is a schematic arrangement plan for illustrating a read operation of a nonvolatile memory device according to example embodiments, FIG. 13 and FIG. 14 are cross-sectional views for illustrating a read operation of a nonvolatile memory device according to example embodiments, and FIG. 15 is a graph of voltage-current characteristics obtained by simulation for illustrating a read operation of a nonvolatile memory device according to example embodiments. FIG. 13 illustrates a case where the program cell is read, and FIG. 14 illustrates a case where the erase cell is read.

Referring to FIG. 12, one memory transistor, e.g., the cell which includes a first word line WL0 and a first bit line BL1, may be selected. A first read voltage V_{RE} may be applied to the selected first word line WL0, and a pass voltage V_{PA} may be applied to other word lines WL1, WL2 . . . , and WL31. A second read voltage V_{S2} may be applied to the auxiliary lines SG0, SG1, SG2 . . . , and SG32. The common source line CSL and the second bit line BL2 may be grounded and a third read voltage V_{RB} may be applied to the first bit line BL1. A turn-on voltage V_{ON} may be applied to the source selection line GSL and the string selection line SSL.

For example, the first read voltage V_{RE} may be a voltage of about 0 V, and the second read voltage V_{S2} may be a voltage of about 0.5 V-about 1 V. A turn-on voltage V_{ON} may be a voltage of about 2 V-about 4 V, and a pass voltage V_{PA} may be a voltage above about 7 V. The third read voltage V_{RB} may be above about 1 V. However, these voltage ranges are only for illustrative purpose, and may be varied depending on the dimensions of the nonvolatile memory device.

Referring to FIG. 13, because the electron e exists in the charge storage layer 120, the channel region 112 under the charge storage layer 120 may not be turned on, but only the channel region 112 under the first and second auxiliary gate electrode 130a and 130b may be turned on. Accordingly, the channel 165 may not be connected. Therefore, because the selected memory transistor is turned off, a current through the first bit line BL1 may be measured by a leakage current.

Referring to FIG. 14, because a hole, rather than an electron, is located in the charge storage layer 120, all channel regions 112 under the charge storage layer 120, and the first and second auxiliary gate electrodes 130a and 130b may be turned on. As a result, the channel 170 may be connected. Accordingly, because the selected memory transistor is turned on, the current through the first bit line BL1 may be measured by on-current.

Referring to FIG. 15, because an operating current Id according to a voltage Vg which is applied to the control gate electrode 140 is shown, we may find the threshold voltage from the drawing. In the case of a program cell (a curve C), the threshold voltage may increase compared to an initial case (a curve A), and in an erase cell B, the threshold voltage becomes low. The case of a program cell (a curve C) corresponding to FIG. 13 corresponds to the case where about 180 electrons are stored in the charge storage layer 120, and an erase cell (a curve B) case corresponding to FIG. 14 shows a case where about 60 holes are stored. The method of reading from one cell as described above may be applied similarly to the other cells. In addition, similar to the example embodiment of FIG. 8, in which the second auxiliary line is omitted, and in this case, the source and drain regions and the channel region may exist together.

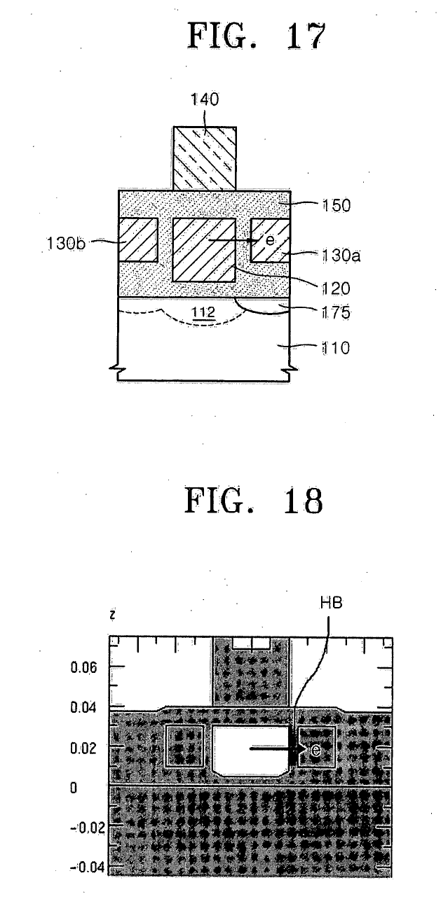

FIG. 16 is a schematic arrangement plan for illustrating an erase operation of a nonvolatile memory device according to example embodiments, FIG. 17 is a cross-sectional view for illustrating an erase operation of a nonvolatile memory device according to example embodiments, and FIG. 18 is a graph of electrical field distribution obtained by simulation for illustrating an erase operation of a nonvolatile memory device according to example embodiments.

Referring to FIG. 16, an erase voltage VER may be applied to the first auxiliary lines SG1, and the second auxiliary lines SG0, SG2 . . . , and SG 32 and the word lines WL0, WL1, WL2 . . . , and WL31 may be grounded. The common source line CSL and the first and second bit lines BL1 and BL2 may be grounded, and a turn-off voltage V_{OFF} may be applied to the source selection line GSL and the string selection line SSL. For example, the erase voltage VER may be a voltage above about 10 V. However, these voltage ranges are only for illustrative purpose, and may be varied depending on the dimensions of the nonvolatile memory device.

Referring to FIG. 17, a channel 175 may be formed only in the channel region 112 under the first auxiliary gate electrode 130a. The electron e of the charge storage layer 120 may be moved to the first auxiliary gate electrode 130a by the electrical field so that it may be removed from the charge storage layer 120. Because the first auxiliary gate electrodes 130a are shared between the charge storage layers 120 which are on both sides of the first auxiliary gate electrodes 130a, data of all charge storage layers 120 may be erased at the same time. Referring to FIG. 17 and FIG. 18, an electrical field HB above about 10 MeV/cm may be made between the charge storage layer 120 and the first auxiliary gate electrode 130a.

On the other hand, in a modification of example embodiments, it also may be possible to apply an erase voltage to the second auxiliary gate electrode 130b, and to ground the first auxiliary gate electrode 130a. Though it may be possible to apply an erase voltage to all of the first and second auxiliary gate electrodes 130a and 130b, the erase voltage may be larger than that of example embodiments.

The erase method of example embodiments as described above may be applied similarly to other embodiments. The above descriptions of example embodiments are provided for illustrative and description purposes. Example embodiments may not be limited the embodiments as described above, and it is obvious that various modifications and changes are possible by combining the example embodiments by those skilled in the art without departing from the scope of example embodiments.

In the nonvolatile memory device according to example embodiments, the auxiliary gate electrodes may be formed with a finer width than the source and drain regions formed by impurity doping, which contributes to improving the degree of integration of the nonvolatile memory device.

In addition, because the auxiliary gate electrodes shield the charge storage layers, the effect on adjacent memory transistors by the charge in the charge storage layers may be minimized or reduced. Therefore, the interference between the charge storage layers, for example, the interference upon a read operation may be suppressed, so that the charge storage layers may be arranged more closely than in the conventional art, and the degree of integration of a nonvolatile memory device may be further enhanced.

What is claimed is:

1. A nonvolatile memory device, comprising:
a semiconductor substrate;
at least one charge storage layer on the semiconductor substrate;
at least one control gate electrode on the at least one charge storage layer; and
at least one first auxiliary gate electrode on one side of and apart from the at least one charge storage layer, and isolated from the semiconductor substrate.

2. The nonvolatile memory device of claim 1, further comprising:
at least one second auxiliary gate electrode on the other side of and apart from the at least one charge storage layer, and isolated from the semiconductor substrate.

3. The nonvolatile memory device of claim 1, wherein the at least one control gate electrode is a plurality of control gate electrodes which are disposed across the semiconductor substrate, the at least one charge storage layer is a plurality of charge storage layers which are interposed between the semiconductor substrate and the plurality of control gate electrodes, and the at least one first auxiliary gate electrode is a plurality of first auxiliary gate electrodes which are alternately disposed between the plurality of charge storage layers and which are isolated from the semiconductor substrate.

4. The nonvolatile memory device of claim 3, further comprising at least one second auxiliary gate electrode on the other side of and apart from the at least one charge storage layer, and isolated from the semiconductor substrate, wherein the at least one second auxiliary gate electrode is a plurality of second auxiliary gate electrodes which are alternately disposed with the plurality of first auxiliary gate electrodes between the plurality of charge storage layers and which are isolated from the semiconductor substrate.

5. The nonvolatile memory device of claim 2, wherein the at least one control gate electrode extends so as to enclose a side wall of the at least one charge storage layer in a direction different from the direction in which the at least one first auxiliary gate electrode and the at least one second auxiliary gate electrode are arranged.

6. The nonvolatile memory device of claim 2, further comprising:
a channel region defined in the semiconductor substrate under the at least one charge storage layer and the at least one first auxiliary gate electrode and the at least one second auxiliary gate electrode.

7. The nonvolatile memory device of claim 1, wherein the semiconductor substrate includes a semiconductor nanowire on a body insulation layer.

8. The nonvolatile memory device of claim 1, further comprising:
an interlayer insulating layer formed between the semiconductor substrate, the at least one charge storage layer, the at least one control gate electrode and the at least one first auxiliary gate electrode.

9. The nonvolatile memory device of claim 1, wherein the at least one charge storage layer includes polysilicon, metal, a silicon nitride film, quantum dots, or nanocrystals.

10. The nonvolatile memory device of claim 1, wherein the semiconductor substrate includes a bulk semiconductor wafer.

11. The nonvolatile memory device of claim 1, wherein the semiconductor substrate includes a semiconductor layer on a body insulation layer.

12. The nonvolatile memory device of claim 1, wherein the at least one first auxiliary gate electrode includes polysilicon or metal.

13. The nonvolatile memory device of claim 1, further comprising:
a source region or a drain region formed on the other side of the at least one charge storage layer.

14. The nonvolatile memory device of claim 3, further comprising:
a source region or a drain region defined in the semiconductor substrate so as to be alternately disposed with the plurality of first auxiliary gate electrodes between the plurality of charge storage layers.

15. A method of operating the nonvolatile memory device comprising:
applying a first program voltage to a control gate electrode and a second program voltage to a first auxiliary gate electrode in order to inject a charge from a semiconductor substrate to a charge storage layer.

16. The method of claim 15, wherein a channel region of the semiconductor substrate under the control gate electrode and the first auxiliary gate electrode is turned on.

17. The method of claim 15, wherein the nonvolatile memory device further includes a second auxiliary gate electrode isolated from the semiconductor substrate and on the other side of the charge storage layer, and the second program voltage is applied to the second auxiliary gate electrode.

18. The method of claim 15, further comprising:
applying a first read voltage to the control gate electrode and a second read voltage to the first auxiliary gate electrode, which reads data from the charge storage layer.

19. The method of claim 18, wherein a channel region of the semiconductor substrate under the first auxiliary gate electrode is turned on, and the channel region of the semiconductor substrate under the charge storage layer is turned on or turned off depending on a data state in the charge storage layer.

20. The method of claim 18, wherein the nonvolatile memory device further includes a second auxiliary gate electrode isolated from the semiconductor substrate and on the other side of the charge storage layer, and the second read voltage is applied to the second auxiliary gate electrode.

21. The method of claim 15, further comprising:
applying an erase voltage to the first auxiliary gate electrode, which erases data stored in the charge storage layer.

22. The method of claim 21, wherein the control gate electrode and the semiconductor substrate are grounded.
